(19) United States
(12) Patent Application Publication
(10) Pub. No.: US 2011/0303935 A1
(43) Pub. Date: Dec. 15, 2011

(54) LIGHT SOURCE MODULE WITH LUMINESCENCE IN LENS

(75) Inventor: JYH-LONG CHERN, Chu-Nan (TW)

(73) Assignee: FOXSEMICON INTEGRATED TECHNOLOGY, INC., Chu-Nan (TW)

(21) Appl. No.: 12/813,116

(22) Filed: Jun. 10, 2010

(51) Int. Cl. H01L 33/58

(52) U.S. Cl. 257/98; 257/E33.068

(57) ABSTRACT

The disclosure relates to a light source module comprising a substrate having circuits, at least one light emitting diode (LED) die positioned on the substrate, and at least one luminescence containing lens over the LED die with a light-converting portion having an inverted truncated pyramid-shaped structure with a spherical top. The light-converting portion scatters light generated by the LED die and converts the light into a different color. The light-converting portion has a small bottom end conformably located on the LED die and a large top end which is a portion of an outer contour of the lens.

### BACKGROUND

1. Technical Field

The present disclosure generally relates to light source modules and particularly, to a light source module of light emitting diodes which generates white lights.

2. Description of Related Art

Light emitting diodes (LEDs) have many advantages, such as high luminosity, low operational voltage, low power consumption, compatibility with integrated circuits, easy driving, long-term reliability, and environmental friendliness, which have promoted the LEDs as widely used light source.

A typical light source module uses a blue LED as an initial light source to produce a white light. The blue light emitted from the blue LED strikes luminescence material within the light source module to generate a yellow secondary color light. The combination of the yellow and residual blue lights produces a white light. However, if a proportion of the residual blue light to the yellow light in one lumen of the white light increases, the white lights have a blue color bias. Conversely, if the proportion decreases, the white lights have a yellow color bias.

A light source module generally includes an array of LEDs that form a small area of a light source. Initial lights emitted from each of the LEDs are diffused. The intensity of the initial lights emitted from a LED gradually reduces from the center to the periphery of the LED.

Thus, the intensity of the initial lights emitted from the small area of light source gradually reduces from the center to the periphery of the module. White lights emitted from the module bias the color of the initial lights near the center of the module, and bias the color of the lights fluoresced from fluorescence materials near the periphery of the module. As a result, the color of the white lights is not evenly distributed.

What is needed therefore, is a light source module which can ameliorate the described limitations.

### BRIEF DESCRIPTION OF THE DRAWINGS

Many aspects of the present light source module can be better understood with reference to the following drawings. The components in the drawings are not necessarily drawn to scale, the emphasis instead being placed upon clearly illustrating the principles of the present light source module. Moreover, in the drawings, like reference numerals designate corresponding parts throughout the several views.

FIG. 1 is a schematic view of a LED light source module including a light-converting portion containing luminescence in accordance with a first embodiment.

FIG. 2 is an enlarged, schematic view of the light-converting portion of the LED light source module in FIG. 1.

### DETAILED DESCRIPTION

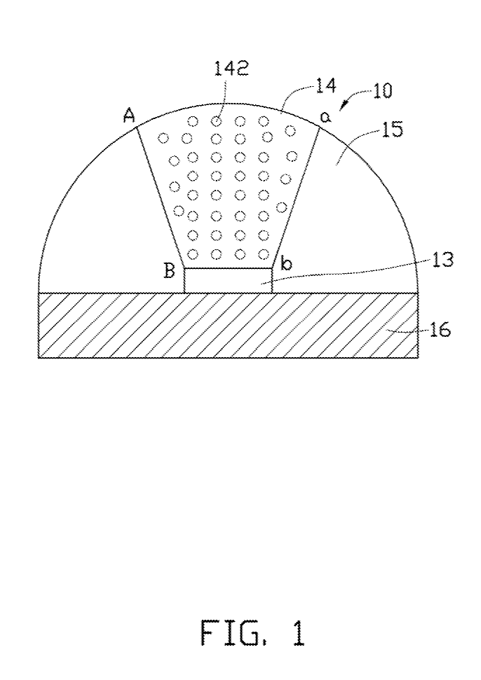

Referring to FIG. 1, a LED light source module 10 including a light-converting portion 14 containing luminescence in accordance with a first embodiment is shown. The light source module 10 includes a substrate 16 having circuits (not shown), a LED die body 13 fixed on the substrate 16, and an encapsulation lens 15 covering the LED die body 13. The luminescence containing encapsulation lens 15 has the light-converting portion 14 filled with numerous luminescence particles 142 which scatter light beams emitted from the LED die body 13. The light-converting portion 14 has a large top end and a small bottom end, wherein the large top end is a portion of a semispherical contour of the encapsulation lens 15, in which a center of the light-converting portion 14 is coincidental with a center of the encapsulation lens 15. The small bottom end of the light-converting portion 14 is conformably positioned on a top of the LED die.

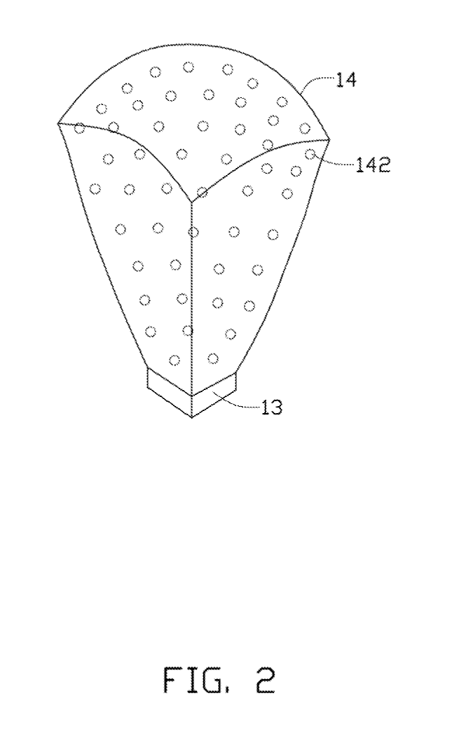

Referring to FIG. 2, an enlarged, schematic view of the light-converting portion 14 is shown, which has a cone-shaped rectangular cylinder structure. The luminescence particles 142 may be distributed in the light-converting portion 14 uniformly or non-uniformly. In the illustrated embodiment, the luminescence particles 142 are distributed in the light-converting portion 14 uniformly.

The luminescence particles 142 may be spherical, cylindrical, or conical with a circular base. In the illustrated embodiment, spherical luminescence particles are employed. The luminescence particles 142 can include phosphorescence and fluorescence. The fluorescence particles 142 are made of a fluorescent material such as Fluorescein Isothiocyanate (FITC), Rhodamine B, Nile blue A or alkaline silicate. The fluorescent particles 142 made of FITC emit green fluorescent light when excited. The fluorescent particles 142 made of Rhodamine B emit yellow fluorescent light when excited. The fluorescent particles 142 made of Nile blue A emit red fluorescent light when excited. The fluorescent particles 142 made of alkaline silicate emit blue fluorescent light when excited.

In the illustrated embodiment, a diameter of each fluorescent particle 142 is in the range from about 1 μm to about 10 μm, and the fluorescent particles 142 progressively decrease slightly in size from a top of the encapsulation lens 15 to a bottom of the encapsulation lens 15 at the substrate 16. Because the fluorescent particles 142 are uniformly distributed in the encapsulation lens 15, and because the diameters of the fluorescent particles 142 are in the range from about 1 μm to about 10 μm, the light beams emitted from the LED die body 13 can be scattered very uniformly.

The luminescence particles 142 not only scatter the light from the LED die body 13, but also illuminate green fluorescent light, yellow fluorescent light, red fluorescent light or blue fluorescent light according to the fluorescent material employed. Furthermore, the light source module 10 can be configured to emit white emitting light by ensuring that fluorescent particles 142 made of different fluorescent materials are present in suitable proportions. For example, by ensuring that luminescence particles 142 made of Rhodamine B and alkaline silicate are present in suitable proportions, the yellow fluorescent light and the blue fluorescent light produced by these fluorescent particles 142 cooperate with the fluorescent light produced by the other fluorescent particles 142 to yield white emitting light. In such case, the luminance of the light source module 10 is improved.

The luminescence particles 142 can be distributed in a region adjacent to the light emitting surface, distal from the LED die body 13. The luminescence particles 142 can also progressively increase in size with an increasing distance away from a center axis of the region. The luminescence particles 142 scatter light emitted from the LED die body 13 to improve luminance and uniformity of illumination.

The included angle between line of A-B and line of a-b is larger than 0 degree and smaller than 180 degree.

The luminescence containing encapsulation lens 15 is located on the light emitting surface of the light source module 10. The luminescence containing encapsulation lens 15 can be silicone, glass, polymethyl methacrylate (PMMA), polycarbonate (PC), epoxy, or polyethylene terephthalate. The luminescence containing encapsulation lens 15 is shaped to increase uniformity of the color temperature vs. the viewing angle. The luminescence containing encapsulation lens 15 can be planar or circular.

The shape of the luminescence containing lens 15 may be designed to improve the color vs. the angle uniformity. Multiple dies may be encapsulated by a single lens.

The luminescence containing encapsulation lens 15 can include a plurality of lens units not limited to two. The shape of the lens units can be convex, concave, spherical, or Fresnel, not being limited to plane convex or concave.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

1. A light source module comprising:
a substrate having circuits;
at least one light emitting diode (LED) die positioned on the substrate; and
at least one luminescence containing lens over the LED die with a light-converting portion having an inverted truncated pyramid-shaped structure with a spherical top, in which the light-converting portion includes luminescence particles scatter light generated by the LED die and transfer the light into a different color,
wherein the light-converting portion has a large top end and a small bottom end conformably positioned on a top of the LED die, the large top end is a portion of an outer contour of the at least one luminescence containing lens, in which a center of the light-converting portion is coincidental with a center of the at least one luminescence containing lens, the outer contour of the at least one luminescence lens has a semispherical shape.

2. The light source module of claim 1, wherein the luminescence particles include at least one of phosphorescence particles and fluorescence particles.

3. The light source module of claim 1, wherein the luminescence particles are distributed in the light-converting portion in one of following manners: uniformly and non-uniformly.

4. The light source module of claim 1, wherein the luminescence containing lens is shaped to increase uniformity of the color temperature vs. viewing angle.

5. The light source module of claim 1, wherein the luminescence particles each have one of following shapes: spherical, cylindrical, and conical with a circular base.

6. The light source module of claim 2, wherein the luminescence containing lens is planar.

7. The light source module of claim 2, wherein the luminescence containing lens is circular.

8. The light source module of claim 1, wherein the luminescence containing lens is silicone, glass, polymethyl methacrylate (PMMA), polycarbonate (PC), epoxy, or polyethylene terephthalate.

9. (canceled)

10. (canceled)

11. (canceled)

12. The light source module of claim 1, wherein the luminescence particles progressively decrease slightly in size from a top of the at least one luminescence containing lens to a bottom of the at least one luminescence containing lens at the substrate.

13. The light source module of claim 12, wherein a diameter of each of the luminescence particles is in the range from about 1 μm to about 10 μm.
